(19) United States
(12) Patent Application Publication
(10) Pub. No.: US 2004/0032214 A1
(43) Pub. Date: Feb. 19, 2004

(54) White light-emitting organic electroluminescent element for back light and liquid crystal display device using the same

(76) Inventors: Sung Soo Lee, Suwon-shi (KR); Jun Ho Lee, Taegu (KR); Jae Soo Yoo, Seoul (KR); Sung Min Cho, Suwon-shi (KR); Chin Ho Park, Taegu (KR)

Correspondence Address: Jacobson Holman, Professional Limited Liability Company, 400 Seventh Street, N.W., Washington, DC, 20004-2218, US

(21) Appl. No.: 10/219,884

(22) Filed: Aug. 16, 2002

(51) Int. Cl. G09G 3/10

(52) U.S. Cl. 315/169.2

(57) ABSTRACT

A white light-emitting organic electroluminescent element for a backlight and a liquid crystal display device using the same. The white light-emitting organic electroluminescent element is useful for a backlight, in which two or three color light-emitting layers are laminated in the form of a thin film, and the liquid crystal display device reproduces natural color tones, resulting from formation of the element at the rear of a liquid crystal display panel. The white light-emitting organic electroluminescent element comprises an anode; a hole injecting layer; a hole transporting layer; an organic electroluminescent layer consisting of two or three color light-emitting layers and one or more controlling layers, the controlling layer being made of a blocking material for controlling the stream of electrons between the light-emitting layers; an electron transporting layer; and a cathode. The white light-emitting organic electroluminescent element prepared according to the present invention can be used instead of a conventional backlight, and in particular, can be applied to a liquid crystal display device for more distinct natural color reproduction.

### BACKGROUND OF THE INVENTION

1. Field of the Invention

The present invention relates to a white light-emitting organic electroluminescent element for a backlight and a liquid crystal display device using the same. More particularly, the present invention relates to a white light-emitting organic electroluminescent element useful as an alternative to a backlight, in which two or three color light-emitting layers are laminated in the form of a thin film, and a liquid crystal display device reproducing natural color tones, resulting from formation of the element at the rear of a liquid crystal display panel.

2. Description of the Related Art

Generally, a backlight is a lighting device that delivers light generated by a lamp placed on the sides of the liquid crystal display panel or behind it evenly over a liquid crystal display panel by diffusion. The liquid crystal display panel displays images on a screen.

A backlight in a conventional liquid crystal display device is shown in FIG. 1 and is composed of a light-emitting source, a reflection sheet, a light guide sheet, a diffusion sheet and a prism. It is mainly placed at the side of a liquid crystal display panel. It has the following undesirable problems: a nonradiative region for a light-emitting source must be present, the structure of the backlight is complex, many components for the backlight are present, manufacturing cost is high and manufacturing time is long. Furthermore, a light-emitting diode or an inorganic electroluminescent element mainly used as the light-emitting source does not provide adequate characteristics in terms of viewing angle of light, color tone, light-emitting intensity and light-emitting efficiency.

Meanwhile, an organic electroluminescent element is composed of an anode, an electron transporting layer, a hole transporting layer, a light-emitting layer and a cathode. Where holes and electrons at the anode and cathode respectively are injected into the light-emitting layer made of organic materials, exitons are created in the light-emitting layer and light is emitted by the energy of the exitons.

The organic electroluminescent element is a thin film element that is driven under a low voltage of about 5 V and has a high brightness surface emission feature. It also can readily change a light-emitting color by proper selection of fluorescent materials.

Until now, studies about the organic electroluminescent element have mainly been focused on elevation of light-emitting efficiency and driving efficiency, improvement of thermal stability, elongation of the lifetime of the element, and the like. However, there have been few studies about using the organic electroluminescent element instead of a backlight in a liquid crystal display device for natural color reproduction.

### SUMMARY OF THE INVENTION

Therefore, the present invention has been made in view of the above problems, and it is an object of the present invention to provide an organic electroluminescent element to be used for a conventional backlight.

It is another object of the present invention to provide a white light-emitting organic electroluminescent element for more distinct natural color reproduction.

It is yet another object of the present invention to provide a liquid crystal display device reproducing natural color tones, resulting from using the white light-emitting organic electroluminescent element for a backlight.

In accordance with one aspect of the present invention, the above and other objects can be accomplished by the provision of a white light-emitting organic electroluminescent element comprising an anode; a hole injecting layer; a hole transporting layer; an organic electroluminescent layer consisting of two or three color light-emitting layers and one or more controlling layer, the controlling layer being made of a blocking material for controlling the stream of electrons between the light-emitting layers; an electron transporting layer; and a cathode.

Preferably, the controlling layer may be deposited in a thickness of 1 to 5 nm.

Also preferably, the blocking material may be one selected from the group consisting of 4,4′-bis[N-(1-naphtyl)-N-phenylamino]biphenyl (α-NPD), bathocuproine or 2,9-dimethyl-4,7-diphenyl-1,10-phenanthroline.

Also preferably, the two color light-emitting layers may be a blue and an orange light-emitting layer or a blue and a yellow light-emitting layer.

In accordance with another aspect of the present invention, there is provided a liquid crystal display device reproducing natural color tones, resulting from formation of the white light-emitting organic electroluminescent element for a backlight at the rear of the liquid crystal display panel.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is an aeroview of a backlight provided at a conventional liquid crystal display device;

FIG. 2 is a liquid crystal display device, in which a white light-emitting organic electroluminescent element is used as an alternative to a backlight, according to the present invention;

FIG. 3 is a cross sectional view showing a structure of a white light-emitting organic electroluminescent element of the present invention; and

FIGS. 4a to 4d are cross sectional views showing laminated structures of white light-emitting organic electroluminescent elements according to embodiments of the present invention.

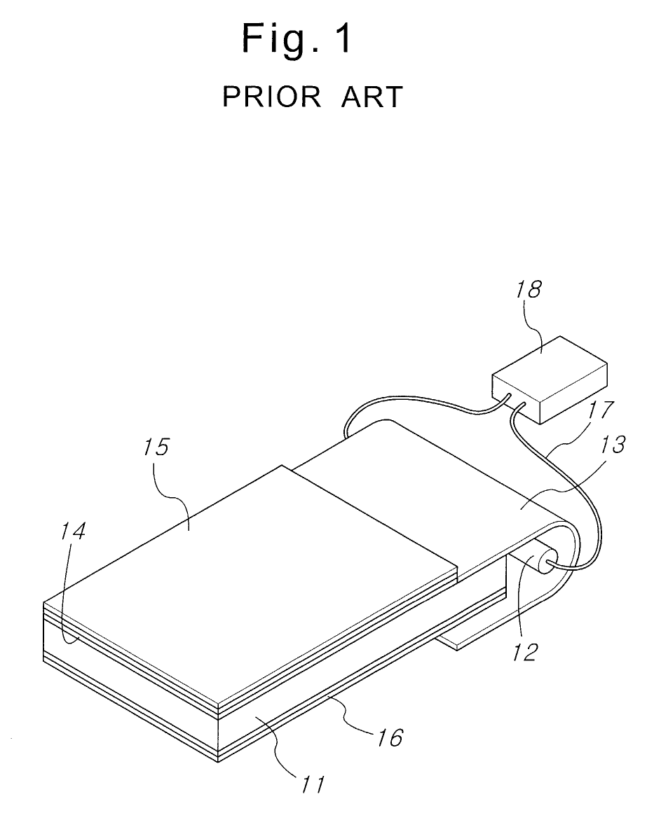

### DESCRIPTION OF THE PREFERRED EMBODIMENTS

Hereinafter, the present invention will be described in more detail with reference to the accompanying figures.

The white light-emitting organic electroluminescent element according to the present invention has two or three color light-emitting layers in the form of thin films and one or more controlling layers for controlling the stream of electrons deposited at one or more positions between the light-emitting layers.

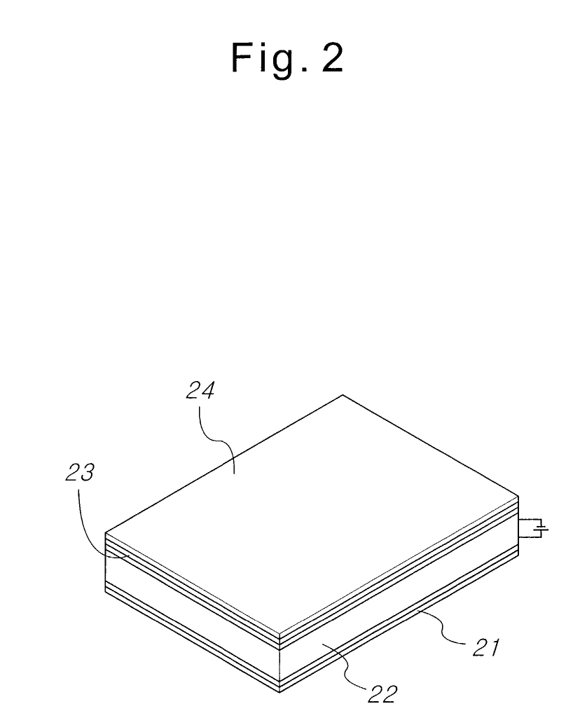

Further, the liquid crystal display device according to the present invention can reproduce natural color tones, resulting from formation of the white light-emitting organic electroluminescent element as an alternative to a backlight at the rear of the liquid crystal display panel, as shown in FIG. 2.

A general organic electroluminescent element comprises, in order, a thin film indium-tin-oxide(ITO)-deposited organic base plate as an anode; a hole transporting layer; a light-emitting layer; an electron transporting layer; an organic material layer for improving interfacial characteristics between an organic electrode and inorganic electrode; and a cathode. In this case, in the absence of a controlling layer, through the lamination of only the two or three color light-emitting layers, it is impossible to emit a desired white light and thus color light is localized toward color light from one of the light-emitting layers.

Therefore, according to the present invention, two or three color light-emitting layers are laminated as a light-emitting layer, and one or more controlling layers made of a blocking material for controlling the stream of electrons between the light-emitting layers are deposited in a thickness of several nm, thereby to form a white light-emitting organic electroluminescent element.

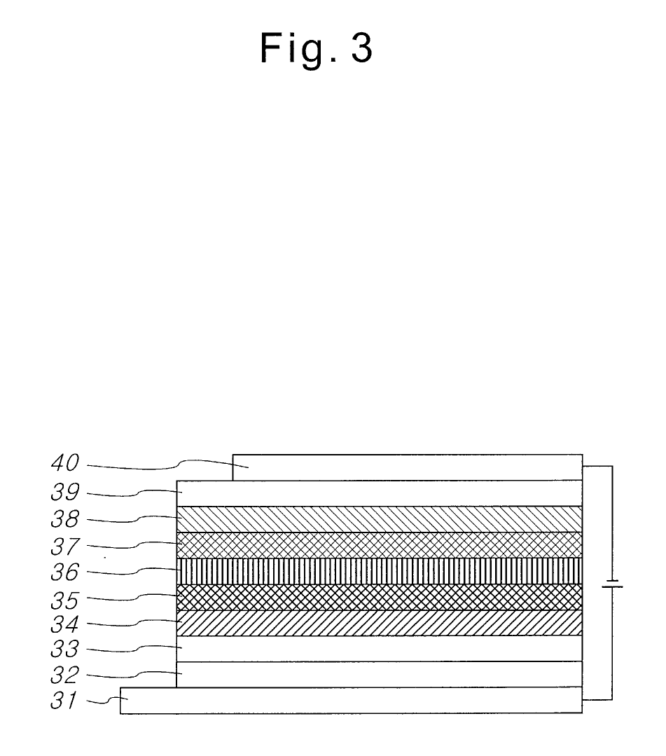

As shown in FIG. 3, the white light-emitting organic electroluminescent element of the present invention is formed by laminating, in order, a transparent conductive anode 31, a hole injecting layer 32, a hole transporting layer 33, a light-emitting layer 34, an electron transporting layer 39 and a metal electrode 40. The light-emitting layer 34 may be three color light-emitting layers or two color light-emitting layers. The controlling layers are formed at all positions between the light-emitting layers or at one or more positions between the light-emitting layers.

The transparent conductive anode 31 can be used by patterning the ITO deposited organic base plate upon a desired shape, primary washing the patterned organic base plate using trichloro ethylene, acetone and methanol each for 10 minutes at an ultrasonic washer, and secondary washing and surface treating the primary washed base plate using oxygen plasma, ultraviolet or ozone plasma.

The hole injecting layer 32 for efficient anode-hole injection may be 4,4,4-tris[biphenyl-3-yl(phenyl)amino]triphenylamine (m-MTDATA) or phthalocyanine copper complex (CuPu) and the hole transporting layer 33 may be N,N′-bis(3-methylphenyl)-N,N′-diphenylbenzidine (TPD) or 4,4-bis[N-(1-naphtyl)-N-phenyl-amino]biphenyl (α-NPD).

With respect to the light-emitting layer for emitting a white light, three color lights, i.e., red, green and blue lights are preferably mixed. In the case of using yellow or orange light created by mixing red and green lights, two color light-emitting layers can emit a white light. An organic electroluminescent material for emitting green light may be tris(8-hydroquinolinato) aluminum (Alq3), an organic electroluminescent material for emitting blue light may be 4,4-bis(2,2-diphenylvinyl)-1,1′-biphenyl (DPVBi), and [2-methyl-6-[2-(2,3,6,7-tetrahydro-1H,5H-benzoquinolizine)-9-ethenyl]-4H-pyran-4-ylidene]propane dinitrile (DCM2) doped Alq3, and an organic electroluminescent material for emitting red light may be 4-(dicyanomethylene)-2-t-butyl-6-(1,1,7,7-tetramethyljulolidyl-9-enyl)-4H-pyran (CDJTB) doped Alq3. Each of the light-emitting layers is deposited under vacuum in a thickness of 10 to 15 nm at a rate of 1 to 2 Å/sec. The total thickness of the light-emitting layers is preferably in the range of 30 to 50 nm. No particular limitation is imposed on the laminating sequence of each of the light-emitting layers.

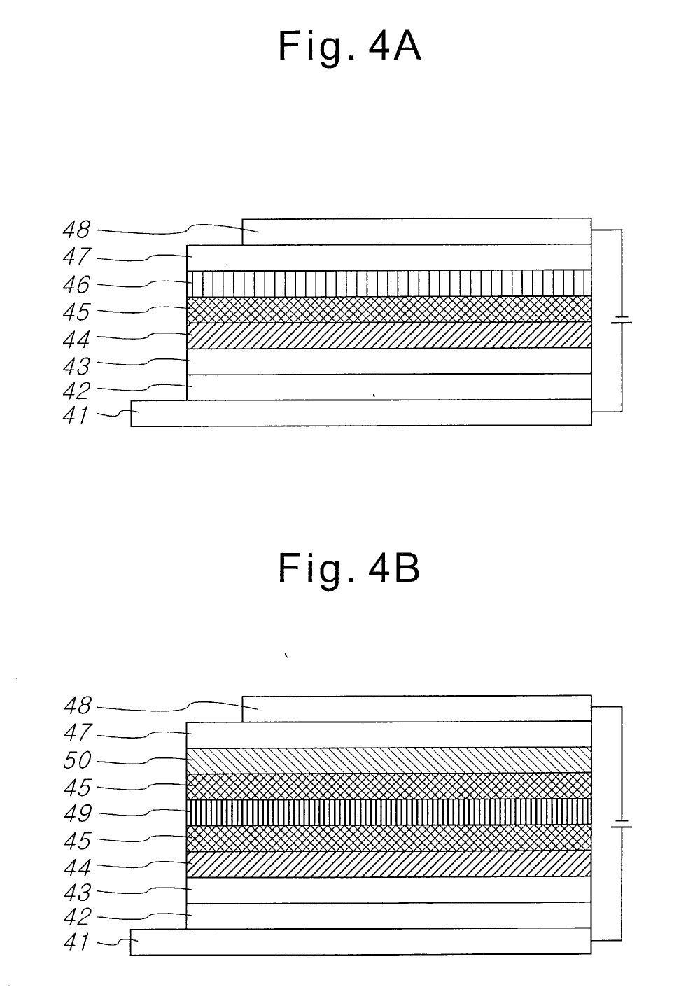

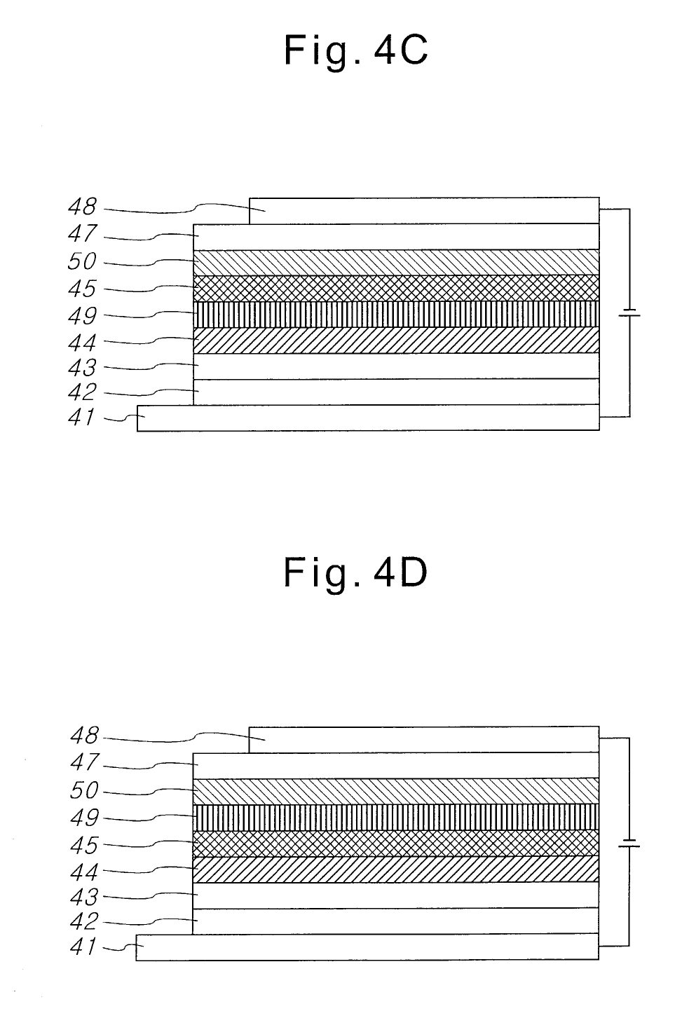

According to the present invention, in order to emit an adequate white light, a controlling layer made of a blocking material must be formed, to thereby control the stream of electrons. FIGS. 4a to 4d show white light-emitting organic electroluminescent elements comprising the light-emitting layers and the controlling layers according to embodiments of the present invention.

FIG. 4a shows an organic electroluminescent element comprising two color light-emitting layers. That is, a controlling layer 45 is present between a blue light-emitting layer 44 and orange light-emitting layer 46. FIGS. 4b to 4d each shows an organic electroluminescent element comprising three color light-emitting layers. That is, a controlling layer 45 may be present at all positions between blue, green and red light-emitting layers 44, 49, 50, or at any one position between them.

The controlling layer serves to control electrons or holes depending on a blocking material. Degree of controlling power may differ due to difference of the band gap of the material. By way of the preferable blocking material may be 4,4-bis [N-(1-naphtyl)-N-phenyl-amino]biphenyl (α-NPD), bathocuproine or 2,9-dimethyl-4,7-diphenyl-1,10-phenanthroline. α-NPD is most preferable.

The controlling layer is preferably deposited under vacuum in a thickness of 1 to 5 nm at a rate of 0.1 to 0.5 Å/sec. If the controlling layer is deposited in a thickness of less than 1 nm, effectiveness as the controlling layer is insufficient because the layer is too thin. While, if the thickness of the controlling layer exceeds 5 nm, the controlling layer blocks the stream of electrons and is unable to emit a white light.

The cathode for providing the light-emitting layers with electrons may be made of metals such as Al, Al-Li alloy, Mg, Mg-As alloy, Ca or Ag. As a result of formation of the cathode and ITO anode, the white light-emitting organic electroluminescent element for the purpose of the present invention is accomplished.

The white light-emitting organic electroluminescent element manufactured by the above method can be used instead of a backlight of a liquid crystal display device. As shown in FIG. 3, where it is formed at the rear of a liquid crystal display panel, a liquid crystal display device in the form of a thin film can generally be prepared.

Hereinafter, the present invention will be described more specifically by examples. It is, however, to be borne in mind that the present invention is by no means limited to or by them.

### EXAMPLE 1

ITO-deposited organic base plate was patterned, and primary washed with trichloro ethylene, acetone and methanol each for 10 minutes at an ultrasonic washer. Then, organic materials and washing reagents were removed using ultra-pure water and the organic base plate was secondarily washed and surface-treated with oxygen plasma, ultraviolet or ozone plasma. On the washed ITO layer 41 were in order deposited phthalocyanine copper complex (CuPu) in a thickness of 10 to 15 nm, 4, 4′-bis [N-(1-naphtyl)-N-phenyl-amino]biphenyl (α-NPD) as a hole transporting layer 43 in a thickness of 25 to 50 nm, 4,4-bis(2,2-diphenylvinyl)-1,1-biphenyl (DPVBi) as a blue light-emitting layer 44 in a thickness of 10 to 15 nm, α-NPD as a controlling layer 45 in a thickness of 1 to 5 nm at a rate of 0.1 to 0.5 Å/sec, and 5,6,11,12-tetraphenylnaphthacene (Rubrene) doped tris(8-hydroquinolinato) aluminum (Alq3) as a orange light-emitting layer 46 in a thickness of 10 to 15 nm. On the light-emitting layer 46 were deposited Alq3 as an electron transporting layer 47 for efficiently transporting electrons in a thickness of 25 to 50 nm and a cathode 48 for providing electrons in a thickness of 150 nm to thereby form an organic electroluminescent element (see FIG. 4a).

### EXAMPLE 2

As shown in FIG. 4b, under the same procedure as the example 1, an ITO layer 41, a hole injecting layer 42 and a hole transporting layer 43 were laminated in order. Then, on the hole transporting layer 43 were deposited DPVBi as a first blue light-emitting layer 44 in a thickness of 10 to 15 nm, and α-NPD as a first controlling layer 45 in a thickness of 1 to 5 nm at a rate of 0.1 to 0.5 Å/sec. On the first controlling layer 45 was deposited Alq3 as a second green light-emitting layer 49 in a thickness of 10 to 15 nm, α-NPD as a second controlling layer 45 in a thickness of 1 to 5 nm, 4-(dicyanomethylene)-2-t-butyl-6-(1,1,7,7-tetramethyljulolidyl-9-enyl)-4H-pyran (DCJTB) doped Alq3 as a third red light-emitting layer 50 in a thickness of 10 to 15 nm, and a cathode 48 in a thickness of 150 nm to thereby form an organic electroluminescent element.

### EXAMPLE 3

As shown in FIG. 4c, under the same manner as the example 1, an ITO layer 41, a hole injecting layer 42 and a hole transporting layer 43 were laminated in order. On the hole transporting layer 43 were deposited DPVBi and Alq3 as a blue light-emitting layer 44 and green light-emitting layer 49, in order, each in a thickness of 10 to 15 nm, and α-NPD as a controlling layer 45 in a thickness of 1 to 5 nm. On the controlling layer 45 were deposited DCJTB doped Alq3 as a third red light-emitting layer 50 in a thickness of 10 to 15 nm and a cathode 48 in a thickness of 150 nm to thereby form an organic electroluminescent element.

### EXAMPLE 4

As shown in FIG. 4d, under the same manner as the example 1, an ITO layer 41, a hole injecting layer 42 and a hole transporting layer 43 were laminated in order. On the hole transporting layer 43 were deposited DPVBi as a blue light-emitting layer 44 in a thickness of 10 to 15 nm, and α-NPD as a controlling layer 45 in a thickness of 1 to 5 nm, in order. On the controlling layer 45 were deposited Alq3 and DCJTB doped Alq3 as a green and a red light-emitting layer 49,50, respectively, each in a thickness of 10 to 15 nm and then a cathode 48 in a thickness of 150 nm to thereby an organic electroluminescent element.

The organic electroluminescent elements prepared according to the above examples emitted an adequate white light by two or three color light-emitting layers and at least one controlling layers formed between the light-emitting layers. Furthermore, the white light-emitting organic electroluminescent elements prepared by the above procedures were superior to conventional light-emitting diodes or inorganic electroluminescent elements in terms of color tone, light-emitting intensity and light-emitting efficiency, to thereby prepare liquid crystal display devices reproducing more distinct natural color tones than when using a backlight.

As apparent from the above description, the white light-emitting organic electroluminescent element prepared according to the present invention has light-emitting layers with a controlling layer therebetween and thus emits an adequate white light, to thereby be used instead of a conventional backlight. In particular, it can be used in a liquid crystal display device to thereby reproduce more distinct natural color tones.

As a result of using the white light-emitting organic electroluminescent element of the present invention as an alternative to a backlight, a liquid crystal display device can be prepared in the form of a thin film. In addition, where the base plate of the organic electroluminescent element is a polymer base plate, the organic electroluminescent element becomes light, thereby to prepare ultra-light, ultra-thin film liquid crystal display device.

Furthermore, the white light-emitting organic electroluminescent element of the present invention can be applied to various display devices such as cost display devices and time display devices, as well as various light-emitting related devices such as a lamp for lighting.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A white light-emitting organic electroluminescent element for a backlight, comprising
an anode;
a hole injecting layer;
a hole transporting layer;
an organic electroluminescent layer consisting of two or three color light-emitting layers and one or more controlling layers, the controlling layer being made of a blocking material for controlling the stream of electrons between the light-emitting layers;
an electron transporting layer; and
a cathode.

2. The white light-emitting organic electroluminescent element for a backlight as set forth in claim 1, wherein the controlling layer is deposited in a thickness of 1 to 5 nm.

3. The white light-emitting organic electroluminescent element for a backlight as set forth in claim 1, wherein the blocking material is one selected from the group consisting of 4,4′-bis[N-(1-naphtyl)-N-phenylamino]biphenyl (α-NPD), bathocuproine or 2,9-dimethyl-4,7-diphenyl-1,10-phenanthroline.

4. The white light-emitting organic electroluminescent element for a backlight as set forth in claim 1, wherein the two color light-emitting layers are a blue and an orange light-emitting layer or a blue and a yellow light-emitting layer.

5. A liquid crystal display device using the white light-emitting organic electroluminescent element as set forth in claim 1 for a backlight.
